(19) United States
(12) Patent Application Publication
(10) Pub. No.: US 2026/0342307 A1
(43) Pub. Date: Oct. 29, 2026

(54) ACOUSTIC WAVE DEVICE UTILIZING ACOUSTIC WAVE REFLECTION PHASE CHANGE

(71) Applicant: PENTASTONE ELECTRONICS, INC., Seongnam-si (KR)

(72) Inventors: Dae Kyu YU, Seoul (KR); Kyoung Joon MIN, Seongnam-si (KR); Kyung Oh KIM, Seoul (KR); Jung-Geun Shin, Ansan-si (KR)

(73) Assignee: PENTASTONE ELECTRONICS, INC., Seongnam-si (KR)

(21) Appl. No.: 19/656,959

(22) Filed: Apr. 23, 2026

(30) Foreign Application Priority Data
Apr. 25, 2025 (KR) 10-2025-0054234

(51) Int. Cl. H03H 9/02; H03H 9/145; H03H 9/25

(52) U.S. Cl. CPC H03H 9/02637; H03H 9/145; H03H 9/25

(57) ABSTRACT

An object of the present invention is to provide an acoustic wave device utilizing acoustic wave reflection phase change, which converts an electrical signal into an acoustic wave of a piezoelectric material using a piezoelectric effect of the piezoelectric material and converts the converted acoustic wave back into an electrical signal, wherein the acoustic wave device can effectively reduce a spurious response on a frequency response and suppress the occurrence of ripples in a passband by adjusting electrode periods of an interdigital transducer and a reflector to control a phase change of reflection of the acoustic wave, thereby canceling multiple reflections.

### CROSS-REFERENCE TO RELATED APPLICATION

This application is based on and claims priority under 35 U.S.C. §119 to Korean Patent Application Nos. 10-2025-0054234 filed on Apr. 25, 2025, in the Korean Intellectual Property Office, the disclosure of which is incorporated by reference herein in its entirety.

### BACKGROUND OF THE INVENTION

### Field of the Invention

The present invention relates to an acoustic wave device that converts an electrical signal into an acoustic wave of a piezoelectric material using a piezoelectric effect of the piezoelectric material and converts the converted acoustic wave back into an electrical signal, and more particularly, to an acoustic wave device having a configuration capable of effectively reducing a spurious response on a frequency response by utilizing an acoustic wave reflection phase change.

Information on National R&D Project supporting the present invention is as follows.

[Project Number] 20240011

[Assignment Number] RS-2024-00398318

[Name of Department] Ministry of Science and ICT

[Research and Management Institution] Institute of Information & Communications Technology Planning & Evaluation

[Research Program Name] Next-Generation Network (6G) Industrial Technology Development

[Research Project Title] Development of Core Components for Broadband FEM for Upper-mid Band Communication Terminals

[Project Implementation Agency] PENTASTONE ELECTRONICS, INC [Research Period] 2025.01.01 ~ 2025.12.31

### DESCRIPTION OF THE RELATED ART

With the development of mobile communication devices such as smartphones and tablets, there is a demand for high performance of acoustic wave elements and devices such as surface acoustic wave resonators and filters using the same. At the same time, due to the miniaturization and integration of devices, more acoustic wave devices need to be mounted in a limited space such as a mobile phone. Therefore, additional configurations for improving the performance of the acoustic wave device are inevitably avoided, and a method of improving the performance of the acoustic wave device within an existing configuration must be studied.

FIG. 1 shows a structure of a conventional typical surface acoustic wave (SAW) resonator. Such a conventional SAW resonator includes an interdigital transducer (IDT) structure 10 formed by continuously arranging metal electrodes in parallel on a piezoelectric substrate (PS) made of a piezoelectric material. When an AC signal voltage is applied to the IDT 10, an electric field is generated between electrodes 11 and 12 inside the IDT, and deformation occurs on the surface of the substrate due to the piezoelectric effect of the piezoelectric substrate, so that a surface acoustic wave (SAW) propagates in both directions of the IDT.

In the process of converting the surface acoustic wave generated on the piezoelectric substrate (PS) by the IDT 10 back into an electrical signal by an output electrode in the IDT or another IDT disposed adjacent thereto, a function of a bandpass filter that passes a frequency component synchronized with the frequency of the surface acoustic wave and attenuates the remaining signals can be performed.

At this point, reflectors 20 and 30 forming gratings 22 of metal thin films around the IDT 10 on the piezoelectric substrate are provided to reflect the surface acoustic wave generated by the IDT 10, thereby reducing loss. That is, the reflectors 20 and 30 of the typical SAW resonator as shown in FIG. 1 serve to confine the surface acoustic wave inside the SAW resonator by reflecting the surface acoustic wave generated from the IDT 10 at both ends of the IDT 10 in accordance with Bragg’s Condition.

As shown in FIG. 1, a plurality of electrodes 11 and 12 provided in the IDT 10 and electrodes 22 of the reflectors 20 and 30 of the typical SAW resonator all have a constant period of pₒ.

In this way, when the periods of the electrodes of the IDT and the electrodes of the reflector are set to the same period, the reflector confines the surface acoustic wave generated from the IDT in the resonator according to the Bragg’s Condition, thereby concentrating surface acoustic wave energy at a resonance frequency to increase a Q-factor. However, since a reflection coefficient occurring in the IDT of a typical SAW resonator is as small as about 8~9%, most of the surface acoustic waves generated from the IDT cause multiple reflections while passing through an IDT boundary.

These multiple reflections occur through various paths and cause interference with the surface acoustic wave generated and propagating in the IDT, thereby causing constructive and destructive interference at other frequencies around the resonance frequency. Therefore, large and small poles and zeros occur at various frequencies, and in particular, small poles and zeros occurring at frequencies lower than the resonance frequency act as a spurious response.

FIG. 2 shows a graph of insertion loss versus frequency for a 1-stage ladder type filter composed of the typical SAW resonator as shown in FIG. 1, and for a series-connected SAW resonator (Series resonator) and a parallel-connected SAW resonator (Parallel resonator) constituting the filter, respectively. That is, a curve indicated by Cfilter represents a frequency curve of the 1-stage ladder type filter, a curve indicated by CSR represents a frequency curve of the series-connected SAW resonator, and a curve indicated by CPR represents a frequency curve of the parallel-connected SAW resonator.

As described above, a spurious response caused by multiple reflections of the surface acoustic wave generated and propagating in the IDT causes a problem of inducing a ripple in a passband, as shown in a portion indicated by A in FIG. 2.

Prior Art Documents related to the present invention are KR10-2024-0041489, JP7272440, WO2008-038481, JP4315199, etc.

### SUMMARY OF THE INVENTION

An object of the present invention is to provide an acoustic wave device utilizing acoustic wave reflection phase change, which converts an electrical signal into an acoustic wave of a piezoelectric material using a piezoelectric effect of the piezoelectric material and converts the converted acoustic wave back into an electrical signal, wherein the acoustic wave device can effectively reduce a spurious response on a frequency response and suppress the occurrence of ripples in a passband by adjusting electrode periods of an interdigital transducer and a reflector to control a phase change of reflection of the acoustic wave, thereby canceling multiple reflections.

An acoustic wave device utilizing acoustic wave reflection phase change according to an embodiment of the present invention includes: a piezoelectric substrate; an interdigital transducer disposed on the piezoelectric substrate and including a plurality of electrode fingers configured to convert an electrical signal into an acoustic wave on the piezoelectric substrate; reflectors respectively disposed in a propagation direction of the acoustic wave generated by the interdigital transducer and configured to reflect the acoustic wave to the interdigital transducer; and an APM electrode unit disposed at an end portion of the interdigital transducer, including a plurality of modulation electrode fingers, and configured to cancel interference of the acoustic wave by changing a reflection phase of the acoustic wave through a variation in a period of the plurality of modulation electrode fingers.

The interdigital transducer includes: a main IDT electrode unit formed by arranging the plurality of electrode fingers generating the acoustic wave at a preset electrode period; and the APM electrode unit respectively disposed between both ends of the main IDT electrode unit and the reflectors, wherein the plurality of modulation electrode fingers of the APM electrode unit are configured such that modulation electrode fingers having two or more periods different from the electrode period of the main IDT electrode unit are alternately arranged to cancel the interference of the acoustic wave between the main IDT electrode unit and the reflectors.

The interdigital transducer includes: a main IDT electrode unit including the plurality of electrode fingers generating the acoustic wave; and the APM electrode unit respectively disposed between both ends of the main IDT electrode unit and the reflectors, wherein the APM electrode unit comprises: at least one first modulation electrode consisting of modulation electrode fingers having a phase change speed of the acoustic wave faster than that of the main IDT electrode unit; and at least one second modulation electrode consisting of modulation electrode fingers having a phase change speed of the acoustic wave slower than that of the main IDT electrode unit, wherein the first modulation electrode is disposed toward the main IDT electrode unit side and the second modulation electrode is disposed toward the reflector side, and the first modulation electrode and the second modulation electrode are alternately arranged.

The interdigital transducer includes: a main IDT electrode unit formed by arranging the plurality of electrode fingers generating the acoustic wave at a preset electrode period; and the APM electrode unit respectively disposed between both ends of the main IDT electrode unit and the reflectors, wherein the APM electrode unit comprises: at least one first modulation electrode consisting of a plurality of modulation electrode fingers having a first modulation period shorter than the electrode period of the main IDT electrode unit such that a phase change speed of the acoustic wave is faster than that of the main IDT electrode unit; and at least one second modulation electrode consisting of a plurality of modulation electrode fingers having a second modulation period longer than the electrode period of the main IDT electrode unit such that the phase change speed of the acoustic wave is slower than that of the main IDT electrode unit, wherein the first modulation electrode is disposed toward the main IDT electrode unit side and the second modulation electrode is disposed toward the reflector side, and the first modulation electrode and the second modulation electrode are alternately arranged.

The interdigital transducer includes: a main IDT electrode unit formed by arranging the plurality of electrode fingers generating the acoustic wave at a preset electrode period; and the APM electrode unit respectively disposed between both ends of the main IDT electrode unit and the reflectors, wherein the APM electrode unit comprises: a first APM set formed by alternately arranging a modulation electrode finger having a period shorter than the electrode period of the main IDT electrode unit and a modulation electrode finger having a period longer than the electrode period of the main IDT electrode unit; and a second APM set extending from an end portion of the first APM set and formed by alternately arranging a modulation electrode finger having a period shorter than the electrode period of the main IDT electrode unit and a modulation electrode finger having a period longer than the electrode period of the main IDT electrode unit.

The APM electrode unit is configured such that a difference value between an average value of the first modulation period and the second modulation period and the electrode period of the main IDT electrode unit is set to 5% or less of the electrode period.

The APM electrode unit is configured such that the number of the plurality of modulation electrode fingers is set to 30% or less of a total number of electrode fingers constituting the interdigital transducer.

The reflector includes: a plurality of reflection electrodes configured to reflect the acoustic wave propagating through the APM electrode unit to the interdigital transducer, wherein a period of the plurality of reflection electrodes is longer than the electrode period of the main IDT electrode unit and is set to a value between the first modulation period and the second modulation period.

The reflector is configured such that a difference value between the period of the plurality of reflection electrodes and the electrode period of the main IDT electrode unit is set to 5% or less of the electrode period of the main IDT electrode unit.

### BRIEF DESCRIPTION OF THE DRAWINGS

FIG. 1 shows a structure of a conventional typical surface acoustic wave (SAW) resonator.

FIG. 2 shows a graph of insertion loss versus frequency for a 1-stage ladder type filter composed of the typical SAW resonator shown in FIG. 1, and for a series-connected SAW resonator (Series resonator) and a parallel-connected SAW resonator (Parallel resonator) constituting the filter, respectively.

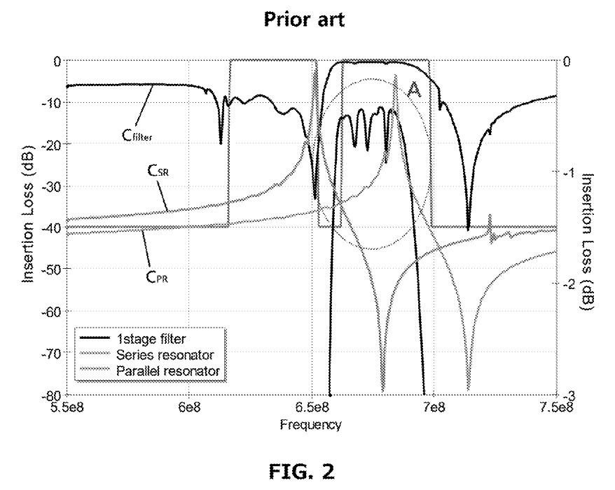

FIG. 3A shows a basic configuration of an acoustic wave device according to an embodiment of the present invention, and FIG. 3B shows details regarding a change in period of the acoustic wave device shown in FIG. 3A.

FIG. 4A shows a basic configuration of an acoustic wave device according to another embodiment of the present invention, and FIG. 4B shows details regarding a change in period of the acoustic wave device shown in FIG. 4A.

FIG. 5 shows details regarding a change in period of a main IDT electrode unit, an APM electrode unit, and a reflector constituting an acoustic wave device according to still another embodiment of the present invention, while omitting their specific finger configurations.

FIG. 6 shows details regarding a change in period of a main IDT electrode unit, an APM electrode unit, and a reflector constituting an acoustic wave device according to yet another embodiment of the present invention, while omitting their specific finger configurations.

FIG. 7 shows a graph of insertion loss versus frequency of a SAW resonator to which the APM electrode unit as shown in FIGS. 3A-3B is applied, a SAW resonator to which the APM electrode unit of a multiple APM configuration as shown in FIG. 5 is applied (in a case where the period of the reflector is the same as the period of the main IDT electrode unit), and a typical SAW resonator.

FIG. 8 shows a graph of insertion loss versus frequency of a SAW resonator in a case where only the APM electrode unit of the multiple APM configuration as shown in FIG. 5 is applied and the period of the reflector is not adjusted (the same as the period of the main IDT electrode unit), a SAW resonator in a case where the periods of the APM electrode unit of the multiple APM configuration as shown in FIG. 5 and the reflector are adjusted, and a typical SAW resonator.

FIG. 9 shows a graph of a result of comparing responses in a passband of a filter composed of typical SAW resonators and a filter composed of SAW resonators having the APM electrode unit as shown in FIGS. 3A-3B.

### DESCRIPTION OF THE PREFERRED EMBODIMENTS

As described above, in the case of a typical acoustic wave device, an acoustic wave generated and propagating from an IDT electrode causes multiple reflections. In order to solve this problem, there is a method of correcting a propagation path after the acoustic wave is generated; however, the present invention focuses on solving the problem of spurious response generation due to the above-described multiple reflections by modulating a property of the wave itself at an end portion of the interdigital transducer, which is a source where the acoustic wave is generated.

For example, the acoustic wave device according to an embodiment of the present invention can push out or cancel spurious energy to another frequency by actively controlling a phase speed at the time of wave generation through alternating modulation that sharply decreases and then increases a period of an electrode finger located at an end portion of an interdigital transducer generating an acoustic wave.

Specific details regarding the acoustic wave device utilizing an acoustic wave reflection phase change according to the present invention will be described in detail with reference to the accompanying drawings.

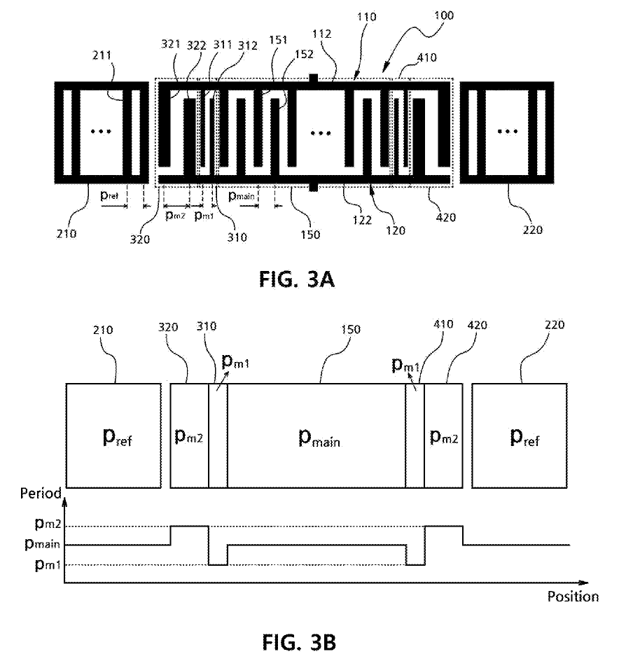

First, a configuration of an acoustic wave device utilizing acoustic wave reflection phase change according to an embodiment of the present invention will be described with reference to FIG. 3.

FIG. 3A shows a basic configuration of an acoustic wave device according to an embodiment of the present invention, and FIG. 3B shows details regarding a change in period of the acoustic wave device shown in FIG. 3A.

As shown in FIGS. 3A and 3B, the acoustic wave device according to an embodiment of the present invention includes an interdigital transducer 100 and reflectors 210 and 220 respectively provided at both end portions thereof, which are all provided on a piezoelectric substrate.

In the drawings, the illustration of the piezoelectric substrate is omitted for convenience, and the same applies hereinafter.

The interdigital transducer 100 is provided on the piezoelectric substrate and converts an electrical signal into an acoustic wave on the piezoelectric substrate, or conversely, converts an acoustic wave on the piezoelectric substrate into an electrical signal, or performs both.

The interdigital transducer 100 includes a plurality of electrode fingers (151, 152, 311, 312, 321, 322, etc.) configured to convert an electrical signal into an acoustic wave on the piezoelectric substrate.

Specifically, as shown in FIG. 3, the interdigital transducer 100 has a configuration in which a plurality of metal electrodes having a comb structure, that is, a plurality of electrode fingers, are divided into an input IDT electrode unit 110 and an output IDT electrode unit 120 so that a plurality of input electrode fingers (151, 311, 321, etc.) and a plurality of output electrode fingers (152, 312, 322, etc.) are alternately arranged. The interdigital transducer 100 includes an input electrode busbar 112 connecting the plurality of input electrode fingers (151, 311, 321, etc.) and an output electrode busbar 122 connecting the plurality of output electrode fingers (152, 312, 322, etc.). When an electrical signal is applied through the input IDT electrode unit 110, an acoustic wave is generated on the piezoelectric substrate by an electric field between the plurality of input electrode fingers (151, 311, 321, etc.) and the output electrode fingers (152, 312, 322, etc.), and the acoustic wave is converted back into an electrical signal and output to the output IDT electrode unit 120.

In this instance, the acoustic wave generated from the interdigital transducer 100 propagates in both directions, that is, the left and right directions in the drawing, respectively.

By providing reflectors 210 and 220 forming gratings of metal thin films at both end portions of the interdigital transducer 100 in a propagation direction of the acoustic wave generated from the interdigital transducer 100 on the piezoelectric substrate, the acoustic wave generated by the interdigital transducer 100 and propagating to the outside is reflected back to the interdigital transducer 100, thereby reducing a loss caused by the propagation of the acoustic wave.

That is, the reflectors 210 and 220 serve to confine the acoustic wave inside the acoustic wave device by reflecting the acoustic wave generated from the interdigital transducer 100 at both ends of the interdigital transducer 100.

However, as described above, most of the acoustic waves generated from the interdigital transducer cause multiple reflections while passing through boundaries thereof, and a cause of spurious response generation is deeply related to the multiple reflections generated between the interdigital transducer and the reflector.

Therefore, adjusting a phase change of these multiple reflections so that they cancel each other out is an effective approach to reduce the spurious response as described above.

To this end, the acoustic wave device according to an embodiment of the present invention intentionally changes phases of the acoustic wave generated and passing through the interdigital transducer and an internally reflected acoustic wave so that they cancel each other out by adjusting a period length of the electrode fingers of the interdigital transducer and/or the reflector.

At this point, it is necessary to maintain performance of the acoustic wave device despite the change in the reflection phase of the acoustic wave, that is, to cancel the spurious response while minimizing a change in a resonance frequency.

As shown in FIG. 3, the acoustic wave device according to an embodiment of the present invention is configured such that the interdigital transducer 100 includes a main IDT electrode unit 150 formed by arranging a plurality of electrode fingers generating the acoustic wave at a preset electrode period, and APM electrode units 310, 320, 410, and 420 respectively provided between both ends of the main IDT electrode unit 150 and the reflectors 210 and 220, and the APM electrode units 310, 320, 410, and 420 each include a plurality of modulation electrode fingers 311, 312, 321, and 322, and are configured to cancel interference of the acoustic wave by changing a reflection phase of the acoustic wave through a variation in a period of the plurality of modulation electrode fingers.

As shown in FIGS. 3A and 3B, the APM electrode unit may be configured to include first modulation electrodes 310 and 410 and second modulation electrodes 320 and 420 provided at both ends of the main IDT electrode unit 150.

At this point, at least one first modulation electrode 310 or 410 may be provided, and at least one second modulation electrode 320 or 420 may also be provided.

Since the above-described APM electrode units are respectively provided at both ends of the main IDT electrode unit 150 with the same configuration, the APM electrode unit provided on one side of the main IDT electrode unit will be described in detail below, and a description of the APM electrode unit provided on the other side of the main IDT electrode unit will be omitted because it has the same configuration as the APM electrode unit on the one side.

The first modulation electrode 310 may consist of first modulation electrode fingers 311 and 312 having a phase change speed of an acoustic wave faster than that of the main IDT electrode unit 150, and the second modulation electrode 320 may consist of second modulation electrode fingers 321 and 322 having a phase change speed of an acoustic wave slower than that of the main IDT electrode unit 150.

As shown in FIG. 3B, an electrode period of the plurality of electrode fingers 151 and 152 constituting the main IDT electrode unit 150 is referred to as Pₘₐᵢₙ, a first modulation period which is a period of the plurality of first modulation electrode fingers 311 and 312 constituting the first modulation electrode 310 is referred to as Pₘ₁, a second modulation period which is a period of the plurality of second modulation electrode fingers 321 and 322 constituting the second modulation electrode 320 is referred to as Pₘ₂, and a period of a plurality of reflection electrodes 211 constituting the reflector 210 is referred to as P_{ref}.

As shown in FIG. 3B, the first modulation period Pₘ₁, which is the period of the first modulation electrode 310, may be set shorter than the period Pₘₐᵢₙ of the main IDT electrode unit 150, and the second modulation period Pₘ₂, which is the period of the second modulation electrode 320, may be set longer than the period Pₘₐᵢₙ of the main IDT electrode unit 150.

A period length of the main IDT electrode unit 150 is Pₘₐᵢₙ, a period length of the first modulation electrode 310 is Pₘ₁, and a period length of the second modulation electrode 320 is Pₘ₂, and as shown in FIG. 3B, Pₘ₁ < Pₘₐᵢₙ < Pₘ₂.

At this point, P_{ref}, which is the period of the reflector 210, may be set to the same period length as the period Pₘₐᵢₙ of the main IDT electrode unit 150.

As described above, by setting the period Pₘ₁ of the APM electrode unit shorter than Pₘₐᵢₙand setting Pₘ₂longer than Pₘₐᵢₙ, but setting each period value of Pₘ₁ and Pₘ₂ such that an overall phase change of the acoustic wave becomes the same as that of the main IDT electrode unit 150, it is possible to cancel the spurious response while minimizing a change in the resonance frequency of the acoustic wave device.

In the case of Pₘ₁ of the first modulation electrode having a period length shorter than the main IDT electrode unit, a phase change speed is fast, which causes more multiple reflections to further increase spurious points, while in the case of Pₘ₂ of the second modulation electrode having a period length longer than the main IDT electrode unit, a phase change speed is slow, so interference occurs in a direction in which the spurious response is canceled.

Therefore, as shown in FIGS. 3A and 3B, the spurious response can be canceled by arranging the first modulation electrode 310 having the Pₘ₁ period at a position close to the main IDT electrode unit 150 and arranging the second modulation electrode 320 having the Pₘ₂ period at a position close to the reflector 210.

Metaphorically speaking, just as a bottleneck phenomenon is reduced as an acoustic wave passes through Pₘ₁, which is a two-lane road, and enters Pₘ₂, which is a four-lane road, interference of the acoustic wave between the reflector 210 and the interdigital transducer 100 can be canceled by reducing the number of multiple reflections occurring in the reflector 210.

As described above, the APM electrode units 310 and 320 can eliminate the spurious response while minimizing a change in a resonance frequency of the acoustic wave device by setting a period such that an overall acoustic wave phase change is substantially the same as that of the main IDT electrode unit 150.

To this end, it is preferable that a difference value between an average value of the first modulation period Pₘ₁ of the first modulation electrode 310 and the second modulation period Pₘ₂ of the second modulation electrode 320 of the APM electrode unit as described above and the electrode period Pₘₐᵢₙ of the main IDT electrode unit 150 is set to 5% or less of the electrode period Pₘₐᵢₙ of the main IDT electrode unit 150.

In addition, in order to minimize a change in a resonance frequency by ensuring that an overall acoustic wave phase change of the APM electrode units 310 and 320 is substantially the same as that of the main IDT electrode unit 150, the number of modulation electrode fingers of the APM electrode units 310 and 320 also needs to be appropriately adjusted.

That is, it is preferable that the total number of the modulation electrode fingers 311, 312, 321, and 322 of the APM electrode units 310 and 320 as described above is set to 30% or less of a total number of electrode fingers constituting the interdigital transducer (the main IDT electrode unit and the APM electrode unit).

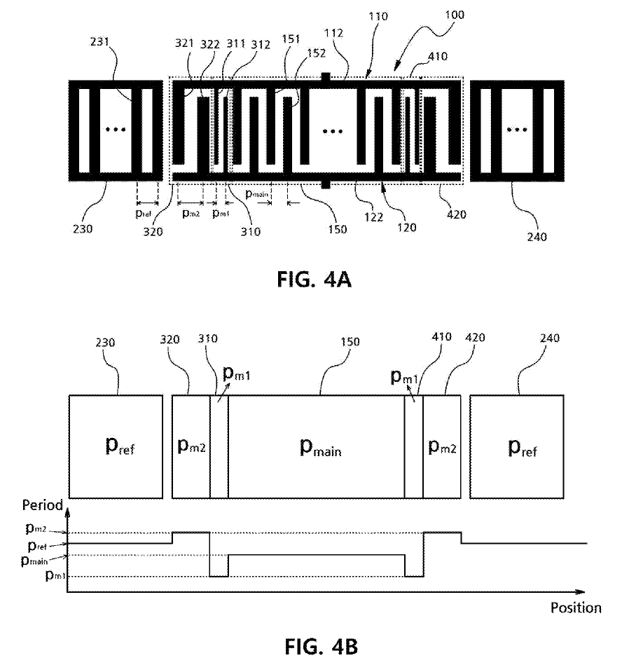

Meanwhile, an acoustic wave device according to another embodiment of the present invention will be described with reference to FIGS. 4A and 4B.

FIG. 4A shows a basic configuration of an acoustic wave device according to another embodiment of the present invention, and FIG. 4B shows details regarding a change in period of the acoustic wave device shown in FIG. 4A.

Previously, the acoustic wave device according to the embodiment shown in FIG. 3 has been described with respect to the case where the period length P_{ref} of the plurality of reflection electrodes 211 of the reflector 210 is the same as the period length Pₘₐᵢₙ of the plurality of electrode fingers 151 and 152 of the main IDT electrode unit 150.

The embodiment shown in FIG. 4 illustrates a case where the electrode period of the main IDT electrode unit 150 and the modulation electrode periods of the APM electrode units 310 and 320 are identical to those of the embodiment shown in FIG. 3 described above, and the periods of the reflection electrodes of the reflectors 230 and 240 are set differently from the electrode period of the main IDT electrode unit.

As shown in FIG. 4, the acoustic wave device according to another embodiment of the present invention may be configured by setting a period length P_{ref} of the reflection electrodes of the reflectors 230 and 240 to a value between Pₘ₂, which is the second modulation period of the second modulation electrode 320 having a phase change speed slower than an electrode period Pₘₐᵢₙ of the main IDT electrode unit 150, and the electrode period Pₘₐᵢₙ of the main IDT electrode unit 150.

That is, the period P_{ref} of the reflectors 230 and 240 may be set longer than the period Pₘₐᵢₙ of the main IDT electrode unit 150 and shorter than the second modulation period Pₘ₂ of the APM electrode unit.

A period length of the main IDT electrode unit 150 is Pₘₐᵢₙ, a period length of the first modulation electrode 310 is Pₘ₁, a period length of the second modulation electrode 320 is Pₘ₂, and a period length P_{ref} of the reflectors 230 and 240 may be set to a value between the period Pₘₐᵢₙ of the main IDT electrode unit 150 and the period Pₘ₂ of the second modulation electrode 320. As shown in FIG. 4B, Pₘ₁ < Pₘₐᵢₙ < P_{ref} < Pₘ₂.

In this way, when a period of the reflection electrode of the reflector is set such that a phase change speed is slower than that of the main IDT electrode unit and faster than that of the second modulation electrode, complex interference between acoustic waves can be canceled more effectively, thereby further improving an effect of suppressing a spurious response.

Even in this case, if an overall phase change of the acoustic wave generated in the interdigital transducer 100 significantly differs from a phase change of an acoustic wave reflected from each of the reflectors 230 and 240, frequency characteristics such as a resonance frequency of the acoustic wave device may be adversely affected. Therefore, it is preferable that a difference value between a period P_{ref} of a plurality of reflection electrodes 231 of the reflector 230 and an electrode period Pₘₐᵢₙ of the main IDT electrode unit 150 is set to 5% or less of the electrode period Pₘₐᵢₙ of the main IDT electrode unit 150.

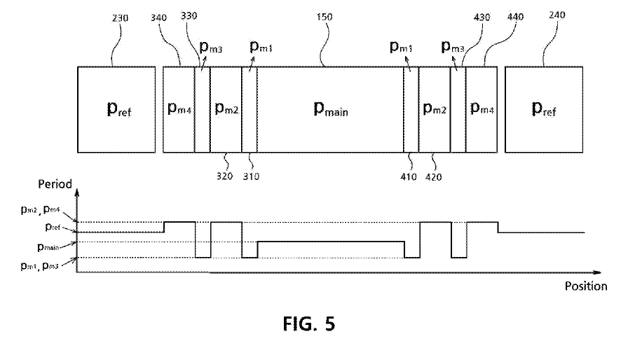

Meanwhile, an acoustic wave device according to still another embodiment of the present invention will be described with reference to FIG. 5.

FIG. 5 shows details regarding a change in period of a main IDT electrode unit 150, APM electrode units 310 to 340 and 410 to 440, and reflectors 230 and 240 constituting an acoustic wave device according to still another embodiment of the present invention, while omitting specific finger configurations thereof.

Similar to the previous embodiments, an acoustic wave device according to still another embodiment of the present invention has a basic configuration in which an interdigital transducer includes a main IDT electrode unit and an APM electrode unit, and reflectors are respectively provided at both end portions of the interdigital transducer.

The acoustic wave device according to the embodiment shown in FIG. 5 has a configuration in which, in the APM electrode unit, a first modulation electrode 310 is arranged toward a main IDT electrode unit 150 side and a second modulation electrode 320 is arranged toward a reflector 230 side, and the first modulation electrode and the second modulation electrode are alternately arranged.

That is, the APM electrode unit of the acoustic wave device according to the embodiment shown in FIG. 5 may have a multiple APM configuration.

The APM electrode unit may be configured to include: a first APM set 310 and 320 formed by alternately arranging a modulation electrode finger having a period Pₘ₁ shorter than an electrode period Pₘₐᵢₙ of the main IDT electrode unit 150 and a modulation electrode finger having a period Pₘ₂ longer than the electrode period Pₘₐᵢₙ of the main IDT electrode unit 150; and a second APM set 330 and 340 extending from an end portion of the first APM set 310 and 320 and formed by alternately arranging a modulation electrode finger having a period Pₘ₃ shorter than an electrode period Pₘₐᵢₙ of the main IDT electrode unit and a modulation electrode finger having a period Pₘ₄ longer than the electrode period Pₘₐᵢₙ of the main IDT electrode unit.

When the APM electrode unit is provided with a multiple APM configuration in this way, it may be more effective in reducing a spurious response of an acoustic wave device. As shown in FIG. 5, when a period of a reflection electrode of a reflector 230 is also set to a modulation period (for example, a period P_{ref} of the reflector is set to a period value between Pₘₐᵢₙ and Pₘ₂) and applied together with the APM electrode unit of the multiple APM configuration described above, it may be more effective in suppressing a spurious response.

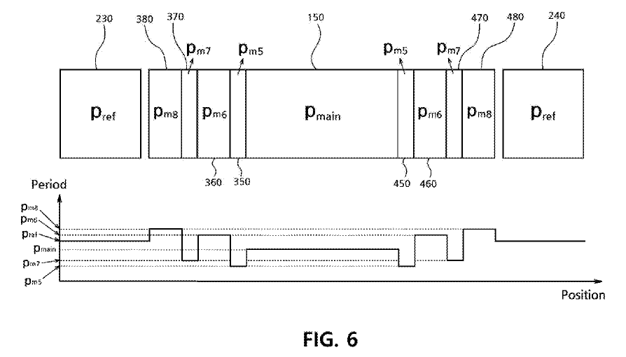

It is also possible to set a change in period of the APM electrode unit having the multiple APM configuration as described above differently for each APM set. This is shown in FIG. 6.

FIG. 6 shows details regarding a change in period of a main IDT electrode unit 150, APM electrode units 310 to 340 and 410 to 440, and reflectors 230 and 240 constituting an acoustic wave device according to yet another embodiment of the present invention, while omitting specific finger configurations thereof.

Similar to the previous embodiments, an acoustic wave device according to yet another embodiment of the present invention has a basic configuration in which an interdigital transducer includes a main IDT electrode unit and an APM electrode unit, and reflectors are respectively provided at both end portions of the interdigital transducer.

The APM electrode unit of the acoustic wave device according to the embodiment shown in FIG. 6 has a multiple APM configuration different from the multiple APM configuration shown in FIG. 5 described above.

The APM electrode units 350 to 380 and 450 to 480 of the acoustic wave device according to the embodiment shown in FIG. 6 are configured to include an APM-1 set 350 and 360 adjacent to a main IDT electrode unit 150 and an APM-2 set 370 and 380 extending therefrom.

The APM-1 set 350 and 360 is formed by alternately arranging a modulation electrode finger having a period Pₘ₅ shorter than an electrode period Pₘₐᵢₙ of the main IDT electrode unit 150 and a modulation electrode finger having a period Pₘ₆ longer than the electrode period Pₘₐᵢₙ of the main IDT electrode unit 150, respectively.

The APM-2 set 370 and 380 extends from an end portion of the above-described APM-1 set 350 and 360, and is formed by alternately arranging a modulation electrode finger having a period Pₘ₇ shorter than an electrode period Pₘₐᵢₙ of the main IDT electrode unit but longer than a short period Pₘ₅ of the APM-1 set 350 and 360 (i.e., a period of a value between Pₘₐᵢₙ and Pₘ₅) and a modulation electrode finger having a period Pₘ₈ longer than a long period Pₘ₆ of the APM-1 set 350 and 360, respectively.

When the APM electrode unit is provided with a multiple APM configuration in this way, it may be more effective in reducing a spurious response of an acoustic wave device. As shown in FIG. 6, when a period of a reflection electrode of a reflector 230 is also set to a modulation period (for example, a period P_{ref} of the reflector is set to a period value between Pₘₐᵢₙ and Pₘ₂) and applied together with the APM electrode unit of the multiple APM configuration described above, it may be more effective in suppressing a spurious response.

Even in the case of the APM electrode unit of the multiple APM configuration as described above, it is preferable that a difference value between an average value of each modulation period (Pₘ₁ to Pₘ₄ or Pₘ₅ to Pₘ₈) and an electrode period Pₘₐᵢₙ of the main IDT electrode unit 150 is set to 5% or less of the electrode period Pₘₐᵢₙ of the main IDT electrode unit 150, and it is preferable that a total number of modulation electrode fingers of the APM electrode unit is set to 30% or less of a total number of electrode fingers constituting the interdigital transducer (the main IDT electrode unit and the APM electrode unit of the multiple APM configuration). The reason is the same as described above, and thus a detailed description thereof will be omitted.

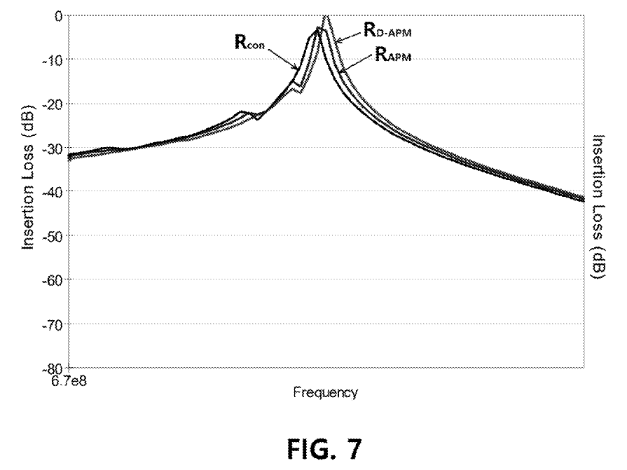

As an acoustic wave device according to the embodiments of the present invention as described above, FIG. 7 shows a graph of insertion loss versus frequency for a SAW resonator to which an APM electrode unit as shown in FIG. 3 is applied, a SAW resonator to which an APM electrode unit of a multiple APM configuration as shown in FIG. 5 is applied (in a case where a period of a reflector is equal to a period of a main IDT electrode unit), and a typical SAW resonator.

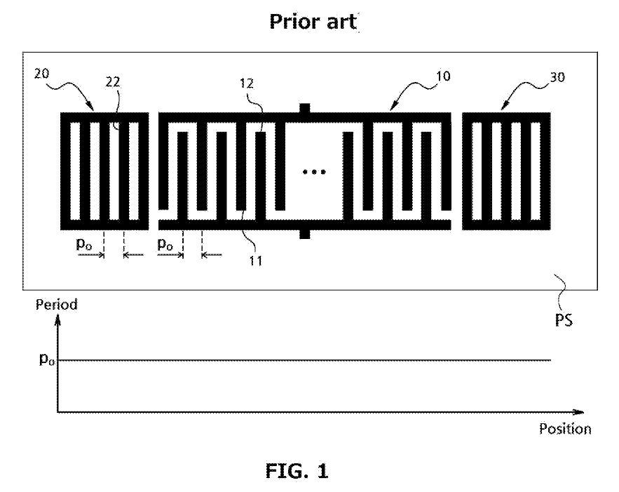

In the graph of insertion loss versus frequency shown in FIG. 7, R_{con} represents a response of a typical SAW resonator (in a case where period lengths of an interdigital transducer and a reflector are constant as shown in FIG. 1), R_{APM} represents a response of a SAW resonator having an APM electrode unit as shown in FIG. 3, and R_{D-APM} represents a response of a SAW resonator having an APM electrode unit of a multiple APM configuration as shown in FIG. 5 (in a case where a period of a reflector is equal to a period of a main IDT electrode unit).

As shown in FIG. 7, it can be seen that insertion loss is more improved in a curve R_{APM} for the SAW resonator having the APM electrode unit than in a curve R_{con} for the typical SAW resonator, and insertion loss is further improved in a curve R_{D-APM} for the SAW resonator of the multiple APM configuration than in R_{APM}.

Due to the improvement in insertion loss in this way, a spurious response of a corresponding SAW resonator can be significantly reduced, and the occurrence of ripples in a passband on a filter response can be significantly suppressed by such a reduction in the spurious response.

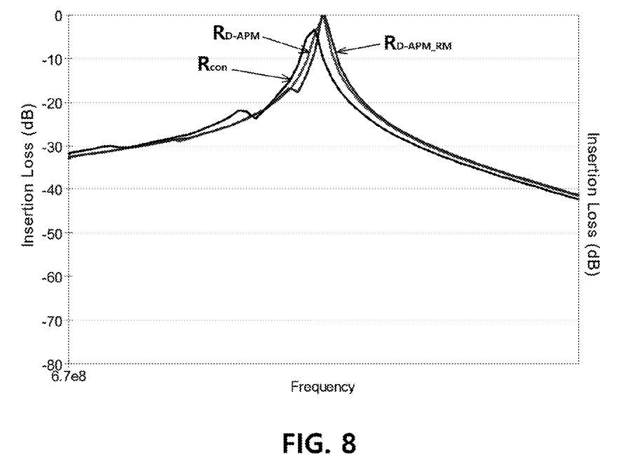

Meanwhile, as an acoustic wave device according to another embodiment of the present invention, FIG. 8 shows a graph of insertion loss versus frequency for a SAW resonator in a case where only an APM electrode unit of a multiple APM configuration as shown in FIG. 5 is applied and a period of a reflector is not adjusted (equal to a period of a main IDT electrode unit), a SAW resonator in a case where periods of an APM electrode unit of a multiple APM configuration as shown in FIG. 5 and a reflector are adjusted, and a typical SAW resonator.

In the graph of insertion loss versus frequency shown in FIG. 8, R_{con} represents a response of a typical SAW resonator (in a case where period lengths of an interdigital transducer and a reflector are constant as shown in FIG. 1), R_{D-APM} represents a response of a SAW resonator having an APM electrode unit of a multiple APM configuration as shown in FIG. 5 (a period of a reflector is equal to a period of a main IDT electrode unit), and R_{D-APM_RM} represents a response of a SAW resonator having an APM electrode unit of a multiple APM configuration as shown in FIG. 5 (a period of a reflector is longer than a period of a main IDT electrode unit and shorter than the longest period in the APM electrode unit).

As shown in FIG. 8, it can be seen that insertion loss is more improved in a curve R_{D-APM} for the SAW resonator having the APM electrode unit of the multiple APM configuration than in a curve R_{con} for the typical SAW resonator, and insertion loss is slightly more improved in a curve R_{D-APM_RM} for the SAW resonator in which the multiple APM configuration and the period of the reflector are adjusted than in R_{D-APM}.

Due to the improvement in insertion loss in this way, a spurious response of a corresponding SAW resonator can be significantly reduced, and the occurrence of ripples in a passband on a filter response can be significantly suppressed by such a reduction in the spurious response.

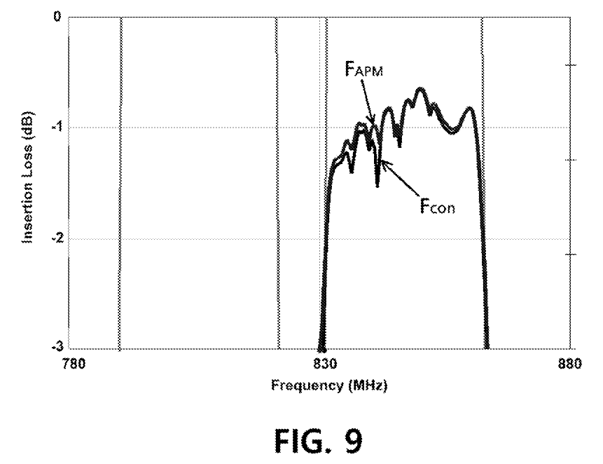

Such an effect of suppressing the occurrence of ripples in a passband can be confirmed through FIG. 9.

FIG. 9 shows a graph of a result of comparing responses in a passband of a filter composed of typical SAW resonators and a filter composed of SAW resonators having an APM electrode unit as shown in FIG. 3.

In the graph of insertion loss versus frequency of the filter shown in FIG. 9, F_{con} represents a response of a filter composed of typical SAW resonators (in a case where period lengths of an interdigital transducer and a reflector are constant as shown in FIG. 1), and F_{APM} represents a response of a filter composed of SAW resonators having an APM electrode unit as shown in FIG. 3.

Comparing response curves of both filters in FIG. 9, it can be seen that the occurrence of ripples is suppressed in a response of a filter composed of an acoustic wave device according to the present invention compared to a conventional filter.

It can be seen that such suppression of ripple generation is a result of reducing a spurious response by adjusting an acoustic wave phase change of an acoustic wave device according to the present invention.

As described above, the present invention proposes a method that can simply and effectively solve a problem that a spurious response occurs as an acoustic wave generated in an IDT is multiply reflected when reflected by a reflector in a conventional acoustic wave device, without a separate additional device or a complex structural change, and accordingly, the present invention has features capable of effectively reducing a spurious response on a frequency response and significantly suppressing the occurrence of ripples in a passband by dividing an interdigital transducer constituting an acoustic wave device into a main IDT electrode unit and an APM electrode unit, and adjusting periods of modulation electrode fingers constituting the APM electrode unit to control a phase change of reflection of an acoustic wave, thereby canceling multiple reflections.

What is claimed is:

1. An acoustic wave device utilizing acoustic wave reflection phase change, comprising:
a piezoelectric substrate;
an interdigital transducer disposed on the piezoelectric substrate and including a plurality of electrode fingers configured to convert an electrical signal into an acoustic wave on the piezoelectric substrate;
reflectors respectively disposed in a propagation direction of the acoustic wave generated by the interdigital transducer and configured to reflect the acoustic wave to the interdigital transducer; and
an APM electrode unit disposed at an end portion of the interdigital transducer, including a plurality of modulation electrode fingers, and configured to cancel interference of the acoustic wave by changing a reflection phase of the acoustic wave through a variation in a period of the plurality of modulation electrode fingers.

2. The acoustic wave device of claim 1, wherein the interdigital transducer comprises:
a main IDT electrode unit formed by arranging the plurality of electrode fingers generating the acoustic wave at a preset electrode period; and
the APM electrode unit respectively disposed between both ends of the main IDT electrode unit and the reflectors,
wherein the plurality of modulation electrode fingers of the APM electrode unit are configured such that modulation electrode fingers having two or more periods different from the electrode period of the main IDT electrode unit are alternately arranged to cancel the interference of the acoustic wave between the main IDT electrode unit and the reflectors.

3. The acoustic wave device of claim 1, wherein the interdigital transducer comprises:
a main IDT electrode unit including the plurality of electrode fingers generating the acoustic wave; and
the APM electrode unit respectively disposed between both ends of the main IDT electrode unit and the reflectors,
wherein the APM electrode unit comprises:
at least one first modulation electrode consisting of modulation electrode fingers having a phase change speed of the acoustic wave faster than that of the main IDT electrode unit; and
at least one second modulation electrode consisting of modulation electrode fingers having a phase change speed of the acoustic wave slower than that of the main IDT electrode unit,
wherein the first modulation electrode is disposed toward the main IDT electrode unit side and the second modulation electrode is disposed toward the reflector side, and the first modulation electrode and the second modulation electrode are alternately arranged.

4. The acoustic wave device of claim 1, wherein the interdigital transducer comprises:
a main IDT electrode unit formed by arranging the plurality of electrode fingers generating the acoustic wave at a preset electrode period; and
the APM electrode unit respectively disposed between both ends of the main IDT electrode unit and the reflectors,
wherein the APM electrode unit comprises:
at least one first modulation electrode consisting of a plurality of modulation electrode fingers having a first modulation period shorter than the electrode period of the main IDT electrode unit such that a phase change speed of the acoustic wave is faster than that of the main IDT electrode unit; and
at least one second modulation electrode consisting of a plurality of modulation electrode fingers having a second modulation period longer than the electrode period of the main IDT electrode unit such that the phase change speed of the acoustic wave is slower than that of the main IDT electrode unit,
wherein the first modulation electrode is disposed toward the main IDT electrode unit side and the second modulation electrode is disposed toward the reflector side, and the first modulation electrode and the second modulation electrode are alternately arranged.

5. The acoustic wave device of claim 1, wherein the interdigital transducer comprises:
a main IDT electrode unit formed by arranging the plurality of electrode fingers generating the acoustic wave at a preset electrode period; and
the APM electrode unit respectively disposed between both ends of the main IDT electrode unit and the reflectors,
wherein the APM electrode unit comprises:
a first APM set formed by alternately arranging a modulation electrode finger having a period shorter than the electrode period of the main IDT electrode unit and a modulation electrode finger having a period longer than the electrode period of the main IDT electrode unit; and
a second APM set extending from an end portion of the first APM set and formed by alternately arranging a modulation electrode finger having a period shorter than the electrode period of the main IDT electrode unit and a modulation electrode finger having a period longer than the electrode period of the main IDT electrode unit.

6. The acoustic wave device of claim 3, wherein the APM electrode unit is configured such that a difference value between an average value of the first modulation period and the second modulation period and the electrode period of the main IDT electrode unit is set to 5% or less of the electrode period.

7. The acoustic wave device of claim 3, wherein the APM electrode unit is configured such that the number of the plurality of modulation electrode fingers is set to 30% or less of a total number of electrode fingers constituting the interdigital transducer.

8. The acoustic wave device of claim 3, wherein the reflector comprises:
a plurality of reflection electrodes configured to reflect the acoustic wave propagating through the APM electrode unit to the interdigital transducer,
wherein a period of the plurality of reflection electrodes is longer than the electrode period of the main IDT electrode unit and is set to a value between the first modulation period and the second modulation period.

9. The acoustic wave device of claim 8, wherein the reflector is configured such that a difference value between the period of the plurality of reflection electrodes and the electrode period of the main IDT electrode unit is set to 5% or less of the electrode period of the main IDT electrode unit.

10. The acoustic wave device of claim 4, wherein the APM electrode unit is configured such that a difference value between an average value of the first modulation period and the second modulation period and the electrode period of the main IDT electrode unit is set to 5% or less of the electrode period.

11. The acoustic wave device of claim 4, wherein the APM electrode unit is configured such that the number of the plurality of modulation electrode fingers is set to 30% or less of a total number of electrode fingers constituting the interdigital transducer.

12. The acoustic wave device of claim 4, wherein the reflector comprises:
a plurality of reflection electrodes configured to reflect the acoustic wave propagating through the APM electrode unit to the interdigital transducer,
wherein a period of the plurality of reflection electrodes is longer than the electrode period of the main IDT electrode unit and is set to a value between the first modulation period and the second modulation period.
